(19) United States
(12) Patent Application Publication
(10) Pub. No.: US 2021/0078735 A1
(43) Pub. Date: Mar. 18, 2021

(54) SATELLITE THREAT MITIGATION BY APPLICATION OF REINFORCEMENT MACHINE LEARNING IN PHYSICS BASED SPACE SIMULATION

(71) Applicant: BAE SYSTEMS Information and Electronic Systems Integration Inc., Nashua, NH (US)

(72) Inventors: Benjamin KAPP, San Diego, CA (US); Wyatt K. HARDING, San Clemente, CA (US); Quoc Toan M. LUONG, Poway, CA (US); Mark J. KOZAR, Clinton, MA (US)

(21) Appl. No.: 16/574,200

(22) Filed: Sep. 18, 2019

(51) Int. Cl. B64G 1/52; B64G 1/36; B64G 1/24; B64G 1/46; G05D 1/00; G06F 17/50; G06N 3/08

(52) U.S. Cl. CPC B64G 1/52; B64G 1/36; B64G 1/242; B64G 1/46; B64G 2001/525; G05D 1/0022; G05D 1/0016; G06F 17/5009; G06N 3/08; G05D 1/0044

(57) ABSTRACT

The system and method for using a reinforcement machine learning based solution for space applications for automated course of action recommendations for the mitigation of threats to space-based assets. The system can be used to mitigate threats to satellites, and it can be used generally as a multi-domain reinforcement machine learning environment for many different kinds of agents, performing many different kinds of actions, under many different simulated environmental conditions.

### FIELD OF THE DISCLOSURE

The present disclosure relates to threat mitigation for space-based assets and more particularly to the use of reinforcement machine learning in a physics based space simulation for threat mitigation.

### BACKGROUND OF THE DISCLOSURE

Within the last decade, machine learning has been revolutionizing industries from transportation to marketing. However, most common machine learning techniques in those industries—supervised and unsupervised learning—fail to perform on extended tasks with delayed responses, such as playing games or managing investments. Over time, researchers have developed for this task new methods of a different subcategory of machine learning called reinforcement learning. Reinforcement learning differs from the other two categories of machine learning because it receives reward values for its predictions, either delayed or immediately, but typically not the correct action or timing itself. Machine agents must try to maximize their cumulative future rewards for their given tasks, be it points or money or even life span, by repeatedly practicing those tasks. This structure has allowed reinforcement learning to perform at or beyond human levels in a variety of games (e.g., chess and go) that supervised and unsupervised cannot.

The reason reinforcement learning research tends to focus on using games is because they are seen as ideal worlds in which machine learning agents can take actions that effect the state of the world and they quite often have built in reward functions (winning the game, game score, etc.). In addition, since these game environments can be simulated on computers, this gives the developer the ability to run many instances of the environment at the same time, as well as running the environment at an accelerated speed. Both of these capabilities are important for reinforcement learning as it allows the system to gain a great deal of experience in a short period of time, and this amount of experience is required for it to learn optimal behaviors.

Wherefore it is an object of the present disclosure to overcome the above-mentioned shortcomings and drawbacks associated with the conventional systems for threat mitigation for space-based assets and more particularly by using a machine learning approach.

### SUMMARY OF THE DISCLOSURE

One aspect of the present disclosure is a method of threat mitigation for space-based assets, comprising: providing a reinforcement machine learning agent trained from a physics based space simulation, wherein the agent is configured to: process environmental information including data about one or more space-based assets and one or more threats; receive warnings from one or more sensors, wherein the warnings require a course of action; and providing a suggestion to an analyst for which course of action to follow to mitigate the one or more threats against the one or more space-based assets.

One embodiment of the method is wherein the system provides a plurality of suggested courses of action along with respective confidence intervals.

Another embodiment of the method is wherein processing environmental information includes assessing sample courses of action in sample situations. In certain embodiments, reinforcement machine learning comprises a reward function to push the system to learn ideal responses to various situations. In some cases, reinforcement machine learning comprises a loss function to calculate how well the system estimates a situation and the ideal action to take.

Yet another embodiment of the method is wherein environmental information is input via a text file, graphical user interface, or direct connection to sensors that output the environmental information. In certain embodiments, a suggestion is output via a file that displays which course of action should be taken along with what the agent took into consideration. In some cases, the file is displayed onto a graphical user interface.

Still yet another embodiment of the method is wherein the system is embedded into a space based asset. In certain embodiments, the space based asset is a satellite.

Another aspect of the present disclosure is a computer program product including one or more non-transitory machine-readable mediums having instructions encoded thereon that, when executed by one or more processors on board a space based asset, result in operations for mitigating threats to the space based asset, the operations comprising: training a reinforcement machine learning agent using data on the space based asset and a plurality of threats; computing a policy and a value of action at a given state on the reinforcement machine learning agent; processing the policy and the value of action with a simulator, wherein the simulator sends back new state information to the reinforcement machine learning agent which computes new policy and new value of action; making a decision by the reinforcement machine learning agent and matching to a course of action; and providing the course of action for execution.

One embodiment of the computer program product further comprises post-processing the course of action.

Another embodiment of the computer program product is wherein providing the course of action is providing the course of action to an operator. In some cases, making the decision is done at an end of a simulation.

These aspects of the disclosure are not meant to be exclusive and other features, aspects, and advantages of the present disclosure will be readily apparent to those of ordinary skill in the art when read in conjunction with the following description, appended claims, and accompanying drawings.

### BRIEF DESCRIPTION OF THE DRAWINGS

The foregoing and other objects, features, and advantages of the disclosure will be apparent from the following description of particular embodiments of the disclosure, as illustrated in the accompanying drawings in which like reference characters refer to the same parts throughout the different views. The drawings are not necessarily to scale, emphasis instead being placed upon illustrating the principles of the disclosure.

FIG. 1 shows an example of a general reinforcement learning diagram.

FIG. 2 shows one embodiment of an abstract, high-level architecture of a reinforcement learning physics-based system according to the principles of the present disclosure.

FIG. 3 shows one embodiment of a process design for one embodiment of a reinforcement learning physics-based system according to the principles of the present disclosure.

FIG. 4A shows how well one embodiment of the system trained with an actor-critic estimates its own status from 0 to 500,000 simulations as detailed in the disclosure.

FIG. 4B shows how the overall performance of one embodiment of the system improves over time from 0 to 500,000 simulations as detailed in the disclosure.

FIG. 4C shows how well one embodiment of the system trained with the actor-critic algorithm estimates the result of its actions from 0 to 500,000 simulations as detailed in the disclosure.

FIG. 5 shows a flow chart of one embodiment of a method according to the principles of the present disclosure.

FIG. 6A shows a beginning portion of a simulation of a space-based asset and a threat according to the principles of the present disclosure.

FIG. 6B shows an intermediate portion of a simulation of a space-based asset and a threat once a course correction occurred according to the principles of the present disclosure.

FIG. 6C shows a late portion of a simulation of a space-based asset and a threat where the threat has been successfully avoided according to the principles of the present disclosure.

FIG. 7A shows a beginning portion of a simulation of a space-based asset and a threat according to the principles of the present disclosure.

FIG. 7B shows a first intermediate portion of a simulation of a space-based asset and a threat where no course correction has occurred according to the principles of the present disclosure.

FIG. 7C shows a second intermediate portion of a simulation of a space-based asset and a threat where no course correction has occurred according to the principles of the present disclosure.

FIG. 7D shows a late portion of a simulation of a space-based asset and a threat where a collision is imminent as no course correction has occurred according to the principles of the present disclosure.

FIG. 8 is a flowchart of one embodiment of a method according to the principles of the present disclosure.

### DETAILED DESCRIPTION OF THE DISCLOSURE

One embodiment of the system of the present disclosure provides a necessary capability for developing reinforcement machine learning based solutions. In certain cases, the system is used for space applications for automated course of action recommendations for the mitigation of threats to space assets. The system of the present disclosure can be used to mitigate threats to satellites, and it can be used generally as a multi-domain reinforcement machine learning environment for many different kinds of agents, performing many different kinds of actions, under many different simulated environmental conditions.

Space is becoming increasingly congested and contested with more and more countries (allies and adversaries alike) developing the capability to place assets on orbit. Concurrently with those capabilities, many countries are pursuing counter-space capabilities that put other's space-based assets at risk. These capabilities are becoming ever more numerous and complex. As such, satellite operators, for example, face an increasingly difficult situation should a space-based conflict begin. There are also space environment issues such as space debris, space junk, and solar flares that may adversely affect the life and operation of a space asset. The technology described herein is designed to assist satellite operators in their decision-making with the ultimate goal of increasing the survivability of space-based assets. In certain embodiments of the present disclosure, a system using reinforcement machine learning is used to mitigate threats, whether man-made or natural, to satellites. The present system is capable of learning to stay on mission as long as possible while still dodging (or otherwise mitigating) threats. The capability for threat mitigation in the space domain can potentially be translated to the air domain. The solution of the present disclosure may be optimized to fit on embedded systems such as satellite, space craft, aircraft, drones, missiles, and the like.

In certain embodiments, where the system is embedded, the agent and environmental information are compressed to fit and run within a computer of each space based asset. The embedded iteration requires less memory and computation using compression techniques from machine learning frameworks. With the embedding, the asset will then autonomously decide which course of action to follow based on its environmental input instead of waiting on a human operator/analyst. In certain embodiments, environmental information refers to an encoding of the state of the one or more space-based asset(s) and adversaries. In the iteration described within the disclosure, it includes the position and velocity of a satellite and a missile, for example.

As to be discussed in more detail herein, one embodiment of the present disclosure was tested using a physics-based space simulator to simulate an environment in which simulated satellites and simulated threats exist. These simulations include situations where a satellite is destroyed (or otherwise disabled) by the threat. In some embodiments, a reward function gives positive rewards to an artificial intelligent agent for staying on mission and negative rewards for an asset being destroyed/disabled.

The world has become increasingly dependent upon satellites in peacetime and in wartime. As such, it is likely that an adversary with the means to do so would target satellites during a conflict. Counter-space threats are becoming increasingly numerous and sophisticated, and a sufficiently advanced adversary may have several different tactics at their disposal. These tactics range from temporary dazzling of sensors to the complete destruction of a space-based asset. During times of conflict, it is likely satellite operators, for example, would face multiple types of threats, potentially concurrently. While pre-planned courses of actions exist, the complexity of threat scenarios can hinder the accuracy of operators' decision. In certain embodiments, a machine learning assistant is a valuable tool for protecting a multitude of space-based assets.

As the space domain continues to become more accessible, with public and private companies launching spacecraft regularly, space is also becoming more crowded. The addition of more spacecraft and resident space objects has and will continue to vastly increase the amount of data on space objects. The increase in spacecraft and space data results in more information to consider before making decisions. In addition to the increase in data, and time to process the data, there is also a decrease in time to make decisions. The operator's timeline to make critical decisions is increasingly shortened by the number of objects in space, their relative speed, and emerging threats to space security from multiple domains.

With the challenges of tracking and understanding thousands of space objects placed into orbit, new objects being launched into space at an ever increasing pace, and multi-domain ground threats such as anti-satellite threats, jamming, laser dazzling, cyber, or other kinetic threats, needs for effective courses of action (COA) and their related tools are substantial.

Currently, there are gaps in space data. For example, possible COA definitions, COA evaluations, COA sharing, COA databases, realistic situational gaming, modeling and simulation, COA decision support, and even COA selection could all be improved. These gaps contribute to a current state of non-integrated, non-shareable potential plans and actions that are difficult to use. These gaps challenge the effectiveness of space operations and lead to shortfalls for multi-domain operations which require acting faster than an adversary. Understanding, timeliness, and confidence in a selection could all be improved through the implementation of tools such as described herein.

Even in the best situations, when COAs are available and prepared in advance, it remains difficult to evaluate and choose the best COA for a given scenario. For example, in the military context tools to perform war gaming are frequently used for operator rehearsal and COA evaluation in a semi-static or somewhat automated simulated scenario. With dynamic situations of a multi-domain conflict, or a multitude of space asset threats where decisions must be made based on rapid physics-based situations and threat avoidance and mitigation situations, systems such as the one disclosed herein are needed to assist decision makers with the best COA.

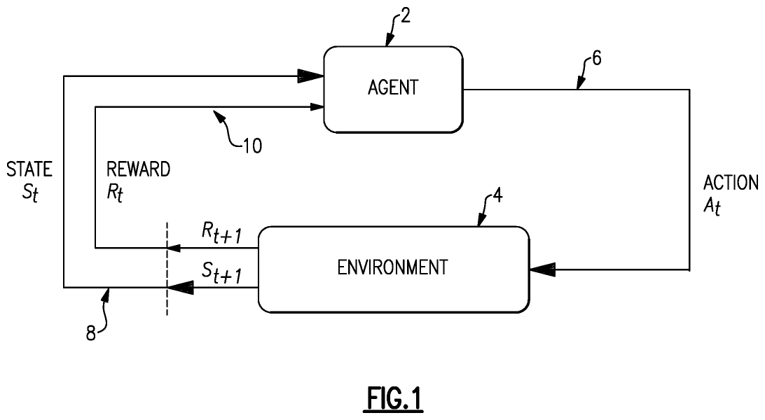

Referring to FIG. 1, shows an example of a reinforcement learning diagram. Generally, an agent 2 provides an action 6 to its environment 4, which in turn supplies corresponding observations, rewards, and completion signal. In one embodiment, a basic scenario, a satellite comes under threat and the agent learns when it needs to take an action to survive. At each time step, the agent 2 outputs an action 6. The environment 4 executes the requested action and increments the time step by 1. The environment 4 then sends the reward 10, next state 8, and completion signal back to the agent 2. The interface enables at least the creation of an environment with a step function, which takes any action the agent makes in the “world” and advances the world forward one step in time, it then returns an observation of the world from the perspective of the agent, along with a reward (positive or negative) calculated based on the current state of the world.

Relative to common problems in the machine learning space, the problem addressed by the present disclosure is different because it is considered a continuous control problem. That is that say for every time step, an agent must learn what is best to do in order to correlate it to a course of action. Other forms of machine learning do not perform as well for this kind of task compared to reinforcement learning. For example, while classification provides a single answer, the model interprets as the best, given some information, it can only provide an answer based on choices it was given during training. The flexibility of a reinforcement learning system allows the system to generate prior courses of actions and even new ones it has not seen yet.

In addition to the type of problem, space asset defense has other nuances that make it a more difficult problem that those previously solved. In the space domain, the area is three dimensional rather than two, adding larger costs for computation if naively transferring a prior solution to a new problem. Furthermore, assets and threats are much more varied. In terms of just the threats, there are kinetic, electronic, energy based threats, and others that require different safety thresholds and solutions. As for assets, the difference between a communication and remote sensing satellite, for example, will necessitate an agent to consider the direction that the asset is facing in addition to its course. For time sensitive tasks or secret tasks, it would also require an agent to have knowledge of the value of the asset's mission relative to an asset's value, requiring it to sacrifice the asset for its mission.

Of course, these complexities require accurate solutions, but they must also be done very quickly due to the speed of threats. For example, to destroy one of its own malfunctioning spy satellites with a ship fired missile, the ship fired missile might be travelling between 3.0 to 4.5 kilometers per seconds—orders of magnitude faster than cars, for example. The combination of these nuances makes it improper to simply transfer prior techniques to the problem of space based assets without large adaptations as those presented herein.

In order for the reinforcement learning system to perform well in the real world, it needs a great deal of realistic experience. Thus, by creating a simulation that is realistic enough (physics-based) then the kinds of experience an agent acquires in such a simulation has the potential to create a model which is real world applicable.

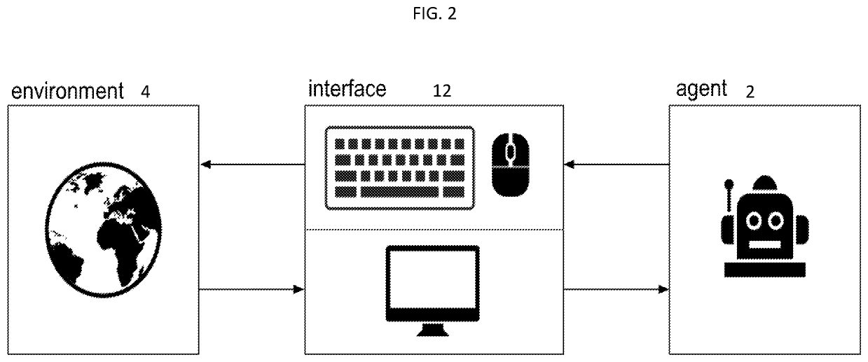

Referring to FIG. 2, one embodiment of an abstract, high-level architecture for a reinforcement learning physics-based system according to the principles of the present disclosure is shown. More specifically, the system comprises an environment 4, an agent 2, and an interface 12. In one embodiment, a physics-based space simulator (e.g. STK, AFSIM, etc.) was used to simulate real world physics and maneuvers of objects (e.g. satellites and anti-satellite missiles) in the environment 4. Since the system of the present disclosure was implemented using a standardized software interface (e.g., Open AI Gym), the interface could be used with Advanced Framework for Simulation, Integration, and Modeling (AFSIM), or another framework and the reinforcement learning algorithms would remain the same. These simulators were used to generate the same kinds of data provided by space data providers, which provide location and velocity information on a variety of space objects. This data was provided as observations to a reinforcement learning agent 2 of the present disclosure so the agent knows where things are in the environment, in a realistic way.

The agent 2 was provided with the ability to take actions in the environment simulator (e.g. move a satellite), and the agent was provided with a reward (positive or negative) based on the state of the world at any given time. For example, negative rewards were given for satellites colliding with missiles, and positive rewards were given for satellites staying on mission (staying on their assigned orbit) in a satellite example. In certain embodiment of the system, the output is given as a percent chance with respect to each possible option, summing up to 100%. In some embodiments of this application, the courses of action are returned with their respective probability, and ordered accordingly for review and implementation by an analyst.

In certain embodiments of the system, the agent provides one or more suggestions to an analyst for which course of action to follow to mitigate the one or more threats against the one or more space-based assets. This refers to the agent's potential to generalize to broader scenarios that may become tougher for a professional to dissect and solve, such as when there are multiple forms of threats or multiple missiles targeting multiple satellites simultaneously.

In one embodiment of the system using reinforcement machine learning in a physics-based space simulation the environment simulation software 4 was STK, but could be any physics-based simulator which supports the modeling of similar kinds of space-based objects. In addition, if the environment simulator can implement a standard reinforcement learning environment interface 12 (e.g. Open Al Gym). The space-based environment simulation provides the capability to simulate objects (e.g. satellites, UAV's, etc.) and various kinds of threats, missiles, electronic warfare, other satellites, debris, (space) weather, and the like. In one embodiment, Open AI Gym was chosen as an interface 12 for reinforcement learning environments.

In one embodiment, the environment was limited to a scenario with a single fixed missile trajectory and a single fixed initial satellite trajectory over 1200 seconds. In this embodiment, due to time and space constraint, time steps were augmented down by a factor of five such that each step the agent sees is equal to five seconds. The environment terminated the scenario either at the last time step or when the distance between the satellite and missile come below a certain safety threshold set in the beginning. In this example, that was 5000 meters. At each time step, the environment sent the agent its state and reward. In one embodiment, only the xyz positions and velocities of the satellite and missile were provided as state information. The agent then decided either to do nothing or perform a given evasive maneuver. The agent initially received five points for staying on mission, zero for performing a maneuver, and a large negative reward for failing to move out of the danger threshold. The goal is to train the agent to stay on mission as long as possible, but move before the impact point.

The reward function is one element of the environment; it determines what the agent will learn. As part of the reinforcement learning system, the reward function was modified to get the “best” results. Initially, the agent received a reward of 5 plus the current time step for staying on mission (e.g. at time step 200, the reward for not moving is 200+5=205), so the later into the mission it was, the more the agent was rewarded for remaining on track. Should it not move far enough away from the missile, which was set as within 5,000 meters distance, it received −500,000 reward for “colliding” with the missile. In the case that it successfully dodged the missile, it received the negation of its distance (−1×distance) from where it would have ended up if it remained on mission. One problem with this reward function was that it rewarded the agent too much for not moving. Another problem was that it punished the agent for successfully dodging the missile. This meant the agent was punished twofold for choosing to move: it received the negative reward for moving and missed out on the positive reward for not moving. Along with the large negative reward for failure, this reward function made it too difficult for the agent to learn when to optimally evade, leading it to instead learn to sacrifice itself for its mission.

In one embodiment, a small, positive scalar reward was given for staying on mission (e.g. +5), zero reward was given for time steps off mission, and a relatively large negative scalar (e.g. −1000) was given for colliding with the missile. In general, the reward function needs to be tuned such that the agent behaves how human operators would want it to. In a more complex scenario, the agent factors in fuel usage, distance from objective, importance of its objective, and the like.

The goal is to have the simulation as realistic as possible. Some considerations include the kind of simulated thrust used for the satellite. Initially, impulse was used, which instantly changes the velocity of the satellite +1 km/s in the X direction. This is unrealistic because velocity cannot change instantly, but rather it accelerates gradually as the satellite performs a thrust maneuver over a period of time up to a desired velocity. In addition, the simulator initially provided the exact position of both the satellite and the missile. However, in the real world, the positions would be known with some measure of uncertainty due to the nature of the accuracy of the measuring devices used to determine these positions. One way of accommodating that uncertainty would be by either increasing the safety threshold for survival such that it includes the worst case scenario where inputs for both satellites and missiles are inaccurate or adding noise to the state sent to the agent. The latter method bears a resemblance to image augmentation techniques used in supervised machine learning in order to improve model performances, which can potentially translate to a more robust reinforcement learning system.

Additionally, the system enhancements could include adding additional threats; jamming, dazzlers, cyber, debris, other satellites and the like. Additional action could be added, as well as maintaining attitude (e.g., magnetic torquer, spin stabilization, mass-expulsion control (MEC), or the like). The threats could also be more realistic. Initially, the missile followed a simple parabolic trajectory, but in the real world an anti-satellite missile most likely would be capable of maneuvering to intercept the satellite within some range. In some cases, a reinforcement learning system for the missile could be used to optimize the likelihood of hitting the satellite and a reinforcement learning system could be used on the satellite which simultaneously tries to dodge the missile.

To be sure, the problem of satellite safety has several constraints that make real life training of reinforcement learning difficult. Satellite safety operates in the real world, which cannot be sped up nor parallelized, and generating scenarios, especially negative ones, is prohibitively expensive since a loss of a satellite creates debris clouds which can damage other satellites. It is believed that if a sufficient number of such experiments occur in the real world it would generate enough debris that space would be largely unusable for all. For all of these reasons it is highly desirable (if not essential) to use a simulation of such a situation (or environment).

In past research, reinforcement learning has demonstrated its capacity to learn from simulations and human observation. For example, between 2008 and 2010, Stanford researchers showed that machine learning can be taught to fly stunts on a real life model helicopter through its observation of a human expert and simulation. This shows that reinforcement learning systems trained on real world grounded simulations have been successfully applied to real world systems. In addition, one of the reasons the Stanford researchers used simulations is because the cost of the real helicopters was high, and thus they could cut costs by training on simulations instead of allowing the machine learning system to learn by crashing real helicopters over and over again.

In certain embodiments of the present disclosure reinforcement learning implementation has been applied to the problem of preserving and protecting space-based assets. Generally, an agent provides an action to its environment, which in turn supplies corresponding observations, rewards, and completion signals. Development of the present disclosure explored approaches to meet needs and tradeoffs in terms of ease of implementation, speed, and performance, along with tackling standard reinforcement learning problems of stability, and the like. The first need of ease of implementation derived from our short window for development, where one would not simply deploy every available method in parallel and wait out run times. Instead, three approaches were selected and applied to the present space threat mitigation problem.

The problem of training stability is inherent in all reinforcement learning algorithms because agent inputs are highly correlated due to their time series nature along with constantly changing decision parameters during the training period. Modern algorithms implement their own solutions to these problems for the sake of convergence.

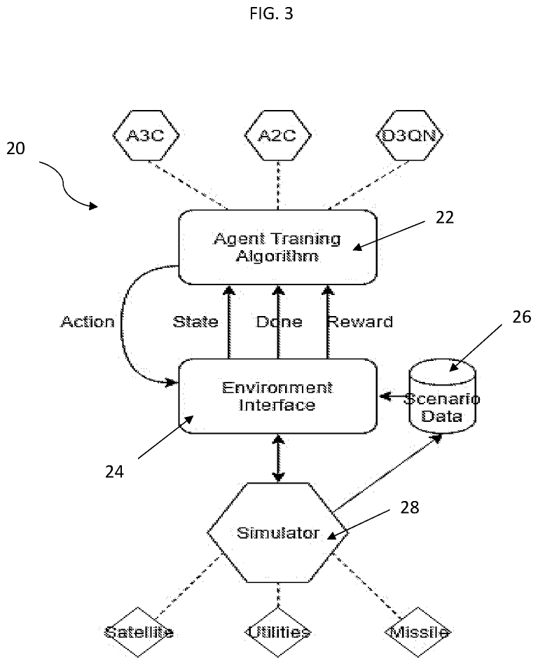

Referring to FIG. 3, one embodiment of a process design for a reinforcement learning physics-based system 20 according to the principles of the present disclosure is shown. The Agent training Algorithm 22 interacts with the Environment Interface 24 that provide three inputs to the Agent Training Algorithm, namely State, Done and Reward. Scenario Data 26 contains data extracted from the Simulator 28 that is employed by the Environment Interface 24. The Simulator 28 interacts with the Environment Interface 24 as the scenarios of satellites, utilities, and missiles are considered.

Testing was performed and is detailed herein, where synchronous Advantage Actor Critic (A3C), Advantage Actor Critic (A2C) and Double Dueling Deep Q Network (D3QN) were tested. Asynchronous Advantage Actor Critic, or A3C, fitted the requirements best. Actor-Critic refers to the structure of how an agent makes its decision. When given some observation, the agent returns two outputs—a value and a policy. The actor evaluates then how agents take actions based on policies while the critic evaluates to how the agents perceive the quality of the observation they received. Advantage simply is how agents perceive the relative quality of an action compared to its other actions. Separating the values of actions with respect to each other allows agents to learn more quickly which is therefore best.

A key to A3C's performance comes from its asynchronous factor. Multiple agents concurrently interact with their own separate environment and update a final global agent at the end of each of their episodes before updating to the global parameters. This process enables the algorithm to experience a variety of scenarios at once and decouples updates to their parameters with their own linear experiences. Concerns with this algorithm lie with the fact that most implementations of it only support CPU, which is much slower than GPU machine learning. Additionally, it requires an individual simulator for each worker thread, which may or may not be feasible depending on the hardware it is implemented on. Nevertheless, its performance across all metrics, was reason enough for experimentation. However, during implementation, there was some difficulty getting this algorithm to converge at extended episode quantities.

As an alternative, Advantage Actor Critic, or A2C was implemented with only one worker in a single process. This allowed a bypass for the need of multiple simulator and the CPU constraints, allowing a quick prototype and iteration on a GPU workstation. Of course, updating every step of A2C would cause problems pertaining to data correlation and gradient stability. Therefore, this issue was addressed by buffering gradient updates to only once every ten episodes.

As another alternative, some improvements were applied to a basic Deep Q Network (DQN) for performance, stability, and faster training. One such improvement was to add a mechanism for experience replay, where a configurable set of experience tuples, <state, action, reward, next state>, were buffered. Old experiences were replaced by new ones and then randomly drawn for more effective training, so that the agent was not just learning from its current actions in the environment.

A Double Dueling Deep Q Network (D3QN) had several advantages that addressed concerns that taking action in a given state may not always have a good reward and that the Q-values of potential actions in a given state can sometimes be overestimated. To address the former, a Q-value represents the reward or how good it is to take an action in a given state as Q(s,a). Further, Q(s,a) was represented as the below equation:

Q(s, a)=V(s)+A(a), where
s=a given state in the set of all states
a=a given action is the set of all actions
V(s)=the value of being is state s
A(a)=the advantage of taking action a

Since it might benefit an agent to stay in its current state more than selecting an action to move to a new state, a Dueling DQN (D2QN) was proposed. Instead of computing Q(s,a) directly as in DQN, D2QN computes V(s) and A(a) separately and combines them later into Q(s,a), thus modifying the basic architecture of a DQN. To address the later, primary and target networks were used to decouple the choice of an action with the generation of a Q-value, respectively, thus stabilizing Q-value shift at each step of training. In single networks, the target and estimated Q-values can fall into destabilizing feedback loops. This simple modification greatly reduced overestimation, while training more robustly and quickly.

The viability and capacity of various modalities of reinforcement learning in threat mitigation were testing against the most basic scenario—a single satellite, a single missile, both on fixed collision trajectories. The agent received position and velocity values for both the satellite and the missile and needed to decide when to perform an evasive maneuver. This scenario was simple enough that it could train quickly on few resources but at the same time required the agent to ensure the survival of the satellite as in a more complex scenario. The threshold for whether or not the satellite survived was based on a distance of 5000 meters from the missile, but that value can be tuned for better visualization.

During initial stages of experimentation, gradient explosions and disappearances were seen as the result of poor state preprocessing. For the A3C implementation, gradients became NaN (not a number) and crashed the process before meaningful results were recorded. For A2C, any result where the satellite collided with the missile lead the agent to issue immediate evasive commands regardless of time step for every episode after. In order to combat these effects, all inputs were reduced by a factor of 1000 because all values of the state were greater than 1000. However, training remained unstable, which lead to instead dividing positional values by 10,000,000 and velocity values by 10,000. Afterwards, training became more stable as all input values were now of the same order of magnitude between −1 and 1.

Different hyper-parameter configurations were experimented with to discover which combinations of values worked the best. With any machine learning system it is imperative to test various learning rates. For A2C a 1e−3 learning rate was used, but smoother convergence was seen using a learning rate of 1e−4. Additionally, different numbers of nodes were used in the hidden layer of the neural network. Similar results were achieved using 256 and 128 hidden nodes, but 128 hidden nodes ran faster. For A3C, a learning rate of 1e−3 and 128 hidden units worked best.

At the start of experimentation, A2C contained an exploration policy that A3C did not. The policy normalized the probability of each action by 0.1 divided by the action space, or 0.05. While this seemed productive for training because it guaranteed some chance of exploration even at convergence, it vastly reduced chances of A2C ever visiting later time states. This lead the A2C agent to perform well in earlier time steps but very randomly at later time steps because of its sparse experience with such inputs. Once normalization was removed, the agent properly visited all ranges of time over its 500,000 episodes and performed better on average.

After training, the agent's decision making process was tested by starting it at every time step of the scenario. Regardless of the starting point, the agent remained on mission path before time step 213 while immediately performing evasive maneuver at time step 213 and after. Additionally, the agent processed all 240 starting positions in less than 40 seconds. Its total output and quick inference together was used to make a course of action (COA) selection more efficiently in the small window available to operators.

In one embodiment, the most common courses of actions were to either slide or scram in order to avoid a threat, with distinction in how far away from the original trajectory of the asset. Other possible courses of actions include using a blocker satellite that is less costly, or requesting missile/kinetic defenses, and the like.

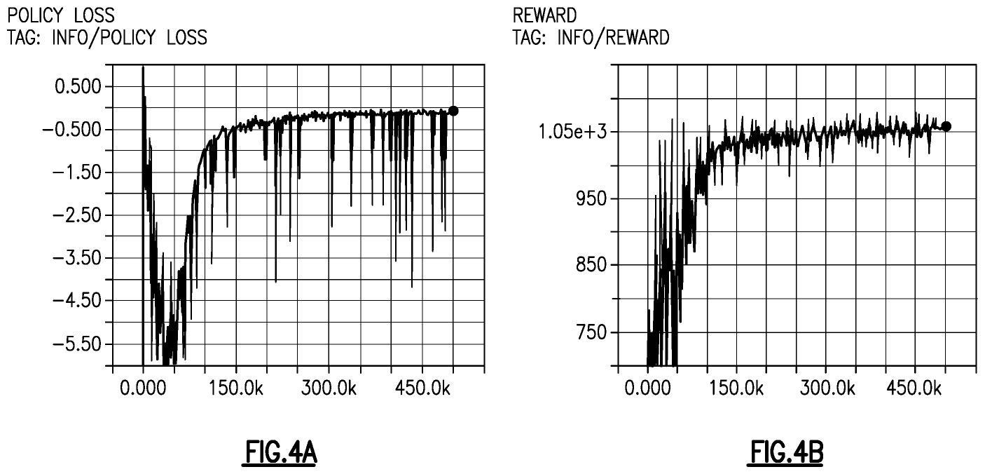

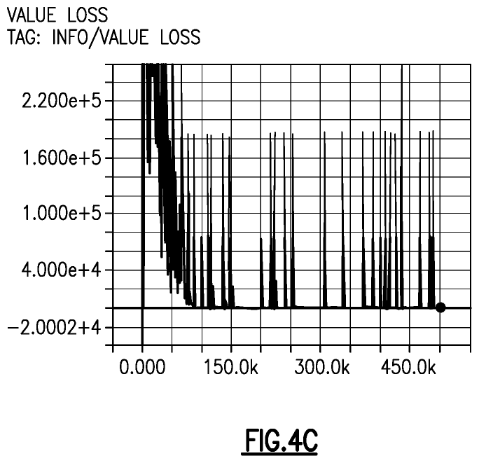

Referring to FIG. 4A, the policy loss of one instance of a reinforcement learning agent's training progress for its policy estimation is shown. This policy estimation refers to what the agent perceives to be its probabilistic distribution of the actions it should take given the state it is in. FIG. 4A shows that the agent starts poorly from 0 iteration to approximately 75,000 iterations, only from then does the agent start to improve. This occurs because, as with most machine learning models, parameters start randomly and thus the agent can only guess randomly. From the 75,000 iteration and onward, the agent begins to learn how it should behave, leading to a plateau where it converges on a general behavior in the one provided scenario.

FIG. 4B supports the pattern of improvement seen in FIG. 4A through its tracking of how much reward the agent receives on average at each training iteration. From this scenario and reward function, the agent plateaus in its performance after 150,000 iterations. The waveform pattern can be attributed to the randomness in the probabilistic distribution of possible actions the agent can take, along with an exploration policy to attempt to gain more information about the problem.

FIG. 4C, although more unstable due to the large negative reward for failure described in this disclosure, still follows the same pattern as seen in FIG. 4A and FIG. 4B. In FIG. 4C, value refers to what the agent predicts it will be rewarded for taking a certain action at a certain state. The difference between what it predicts and what it receives is a single value loss and the average for the iteration is shown on the figure itself. As the agent gains more experience, it becomes better at estimating how it will be rewarded. It will, at times, make an exploratory decision, in which case its guess will have a larger loss value due to the large negative reward. However, these spikes are not indicative of incorrect behavior as the figure continues to trend towards a plateau. As described above in the A2C and A3C sections, the value function assists the policy function to generate an agent that better learns how it should behave to achieve its goal—such as saving a satellite in one embodiment.

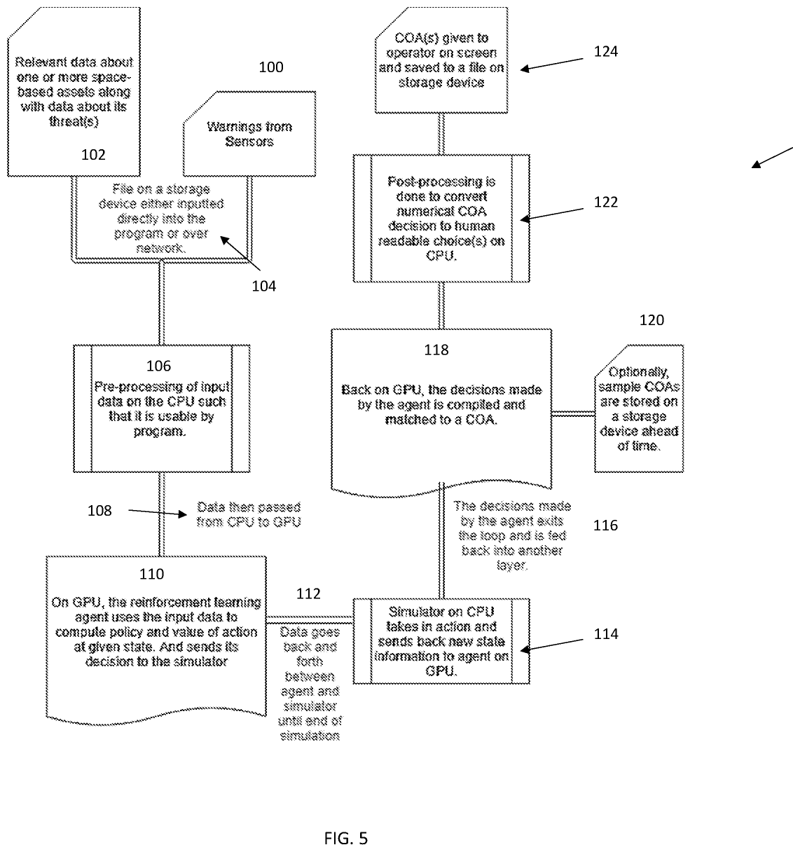

Referring to FIG. 5, a flow chart of one embodiment of a method according to the principles of the present disclosure is shown. More specifically, relevant environmental data, including, but not limited to, input data regarding one or more space-based assets and data regarding one or more threats to the space-based assets 102 as well as input data comprising warning signals from one or more sensors 100 are either directly fed into the threat mitigation system or sent over a network for storage in memory 104. As used herein, warnings refer to any system in place to detect and alert of threats to space-based assets. Preprocessing of input data is conducted on a CPU so that it is later useable by the system 106. Pre-processed data is then passed from the CPU to a GPU 108 in one embodiment of the method of the present disclosure. In certain embodiments, a reinforcement learning agent uses the pre-processed data to compute policies and values for each potential action at a given state on the GPU 110. The agent then sends the resulting decisions to a simulator. Data goes back and forth between the agent and the simulator until the simulation is completed 112. The simulator on the CPU takes in proposed action data from the agent and sends back new state information to the agent based on the proposed action taken 114. At the end of the simulation, the action decisions made by the agent based, in part, on reinforcement learning exits the loop and is fed into another layer 116 for further processing. On the GPU, various action decisions made by the agent are compiled and matched to potential courses of action 118. Optionally, sample courses of action may be stored on a storage device ahead of time for later use by an operator 120.

In certain embodiments, in addition to training with random situations, historical scenarios are leveraged where the situation and its corresponding proper course of action are known. Another method is to generate scenarios varying in scopes of quantity of assets and threats. Then, a (team of) professional(s) observe those scenarios and give their choice for course of action which is fed to the agent. Thus, the agent is given real scenarios and can learn directly how it is supposed to behave and choose in those scenarios.

Still referring to FIG. 5, post-processing is done to convert numerical courses of action generated via the agent in the simulation into human readable course of action choices on a CPU for subsequent selection by an operator 122. The courses of action are displayed on a screen, or the like, and saved in a file on a storage device for selection by an operator and later analysis 124.

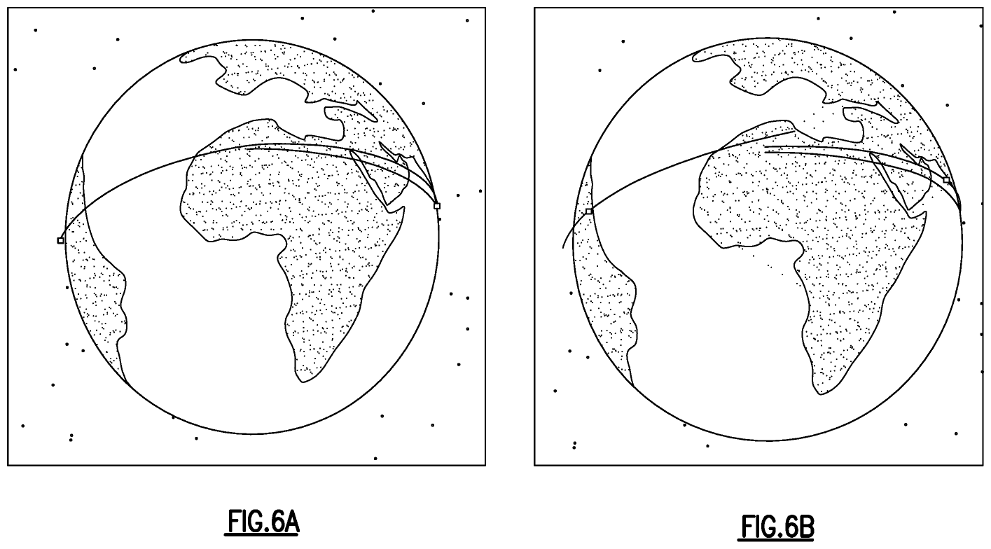

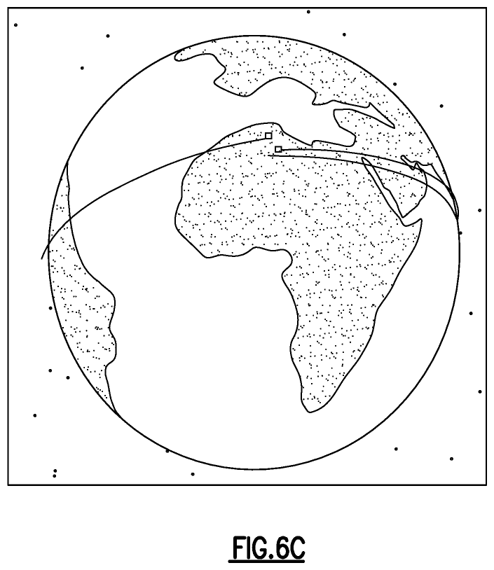

Referring to FIG. 6A-FIG. 6C, a beginning, an intermediate, and a late portion of a simulation of a space-based asset and a threat is shown. More specifically, the threat has been successfully avoided according to the principles of the present disclosure with an early course correction.

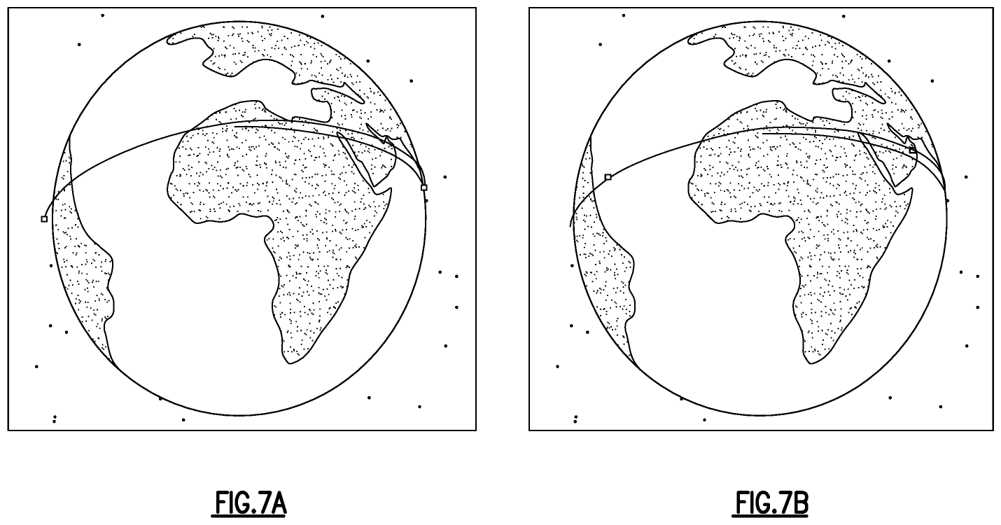

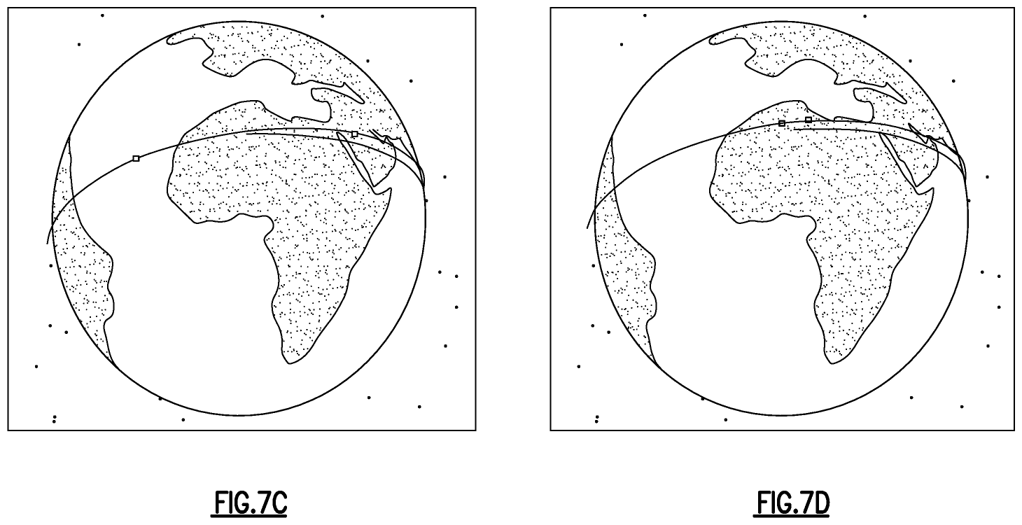

Referring to FIG. 7A-FIG. 7D, a beginning, a first and a second intermediate portion, and a late portion of a simulation of a space-based asset and a threat is shown. More specifically, a collision is imminent in this simulation as no course correction has occurred according to the principles of the present disclosure.

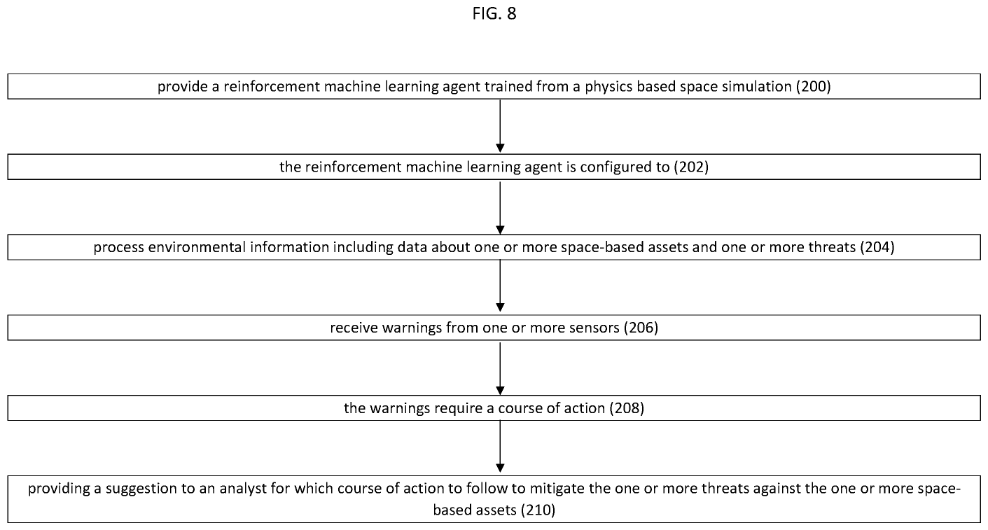

Referring to FIG. 8, a flowchart of one embodiment of a method according to the present disclosure is shown. More specifically, the method of threat mitigation for space-based assets, comprises a reinforcement machine learning agent trained from a physics based space simulation (200). The reinforcement machine learning agent is configured (202) to process environmental information including data about one or more space-based assets and one or more threats (204). The reinforcement machine learning agent receives warnings from one or more sensors (206), where the warnings require a course of action (208). The reinforcement machine learning agent then provides a suggestion to an analyst for which course of action to follow to mitigate the one or more threats against the one or more space-based assets (210).

The computer readable medium as described herein can be a data storage device, or unit such as a magnetic disk, magneto-optical disk, an optical disk, or a flash drive. Further, it will be appreciated that the term “memory” herein is intended to include various types of suitable data storage media, whether permanent or temporary, such as transitory electronic memories, non-transitory computer-readable medium and/or computer-writable medium.

It will be appreciated from the above that the invention may be implemented as computer software, which may be supplied on a storage medium or via a transmission medium such as a local-area network or a wide-area network, such as the Internet. It is to be further understood that, because some of the constituent system components and method steps depicted in the accompanying Figures can be implemented in software, the actual connections between the systems components (or the process steps) may differ depending upon the manner in which the present invention is programmed. Given the teachings of the present invention provided herein, one of ordinary skill in the related art will be able to contemplate these and similar implementations or configurations of the present invention.

It is to be understood that the present invention can be implemented in various forms of hardware, software, firmware, special purpose processes, or a combination thereof. In one embodiment, the present invention can be implemented in software as an application program tangible embodied on a computer readable program storage device. The application program can be uploaded to, and executed by, a machine comprising any suitable architecture.

While various embodiments of the present invention have been described in detail, it is apparent that various modifications and alterations of those embodiments will occur to and be readily apparent to those skilled in the art. However, it is to be expressly understood that such modifications and alterations are within the scope and spirit of the present invention, as set forth in the appended claims. Further, the invention(s) described herein is capable of other embodiments and of being practiced or of being carried out in various other related ways. In addition, it is to be understood that the phraseology and terminology used herein is for the purpose of description and should not be regarded as limiting. The use of “including,” “comprising,” or “having,” and variations thereof herein, is meant to encompass the items listed thereafter and equivalents thereof as well as additional items while only the terms “consisting of” and “consisting only of” are to be construed in a limitative sense.

The foregoing description of the embodiments of the present disclosure has been presented for the purposes of illustration and description. It is not intended to be exhaustive or to limit the present disclosure to the precise form disclosed. Many modifications and variations are possible in light of this disclosure. It is intended that the scope of the present disclosure be limited not by this detailed description, but rather by the claims appended hereto.

A number of implementations have been described. Nevertheless, it will be understood that various modifications may be made without departing from the scope of the disclosure. Although operations are depicted in the drawings in a particular order, this should not be understood as requiring that such operations be performed in the particular order shown or in sequential order, or that all illustrated operations be performed, to achieve desirable results.

While the principles of the disclosure have been described herein, it is to be understood by those skilled in the art that this description is made only by way of example and not as a limitation as to the scope of the disclosure. Other embodiments are contemplated within the scope of the present disclosure in addition to the exemplary embodiments shown and described herein. Modifications and substitutions by one of ordinary skill in the art are considered to be within the scope of the present disclosure.

What is claimed:

1. A method of threat mitigation for space-based assets, comprising:
providing a reinforcement machine learning agent trained from a physics based space simulation, wherein the reinforcement machine learning agent is configured to:
process environmental information including data about one or more space-based assets and one or more threats;
receive warnings from one or more sensors, wherein the warnings require a course of action; and
providing a suggestion to an analyst for which course of action to follow to mitigate the one or more threats against the one or more space-based assets.

2. The method according to claim 1, wherein the system provides a plurality of suggested courses of action along with respective confidence intervals.

3. The method according to claim 1, wherein processing environmental information includes assessing sample courses of action in sample situations.

4. The method according to claim 1, wherein reinforcement machine learning comprises a reward function to push the system to learn ideal responses to various situations.

5. The method according to claim 1, wherein reinforcement machine learning comprises a loss function to calculate how well the system estimates a situation and the ideal action to take.

6. The method according to claim 1, wherein environmental information is input via a text file, graphical user interface, or direct connection to sensors that output the environmental information.

7. The method according to claim 1, wherein a suggestion is output via a file that displays which course of action should be taken along with what the agent took into consideration.

8. The method according to claim 7, wherein the file is displayed onto a graphical user interface.

9. The method according to claim 1, wherein the system is embedded into a space based asset.

10. The method according to claim 1, wherein the space based asset is a satellite.

11. A computer program product including one or more non-transitory machine-readable mediums having instructions encoded thereon that, when executed by one or more processors on board a space based asset, result in operations for mitigating threats to the space based asset, the operations comprising:
training a reinforcement machine learning agent using data on the space based asset and a plurality of threats;
computing a policy and a value of action at a given state on the reinforcement machine learning agent;
processing the policy and the value of action with a simulator, wherein the simulator sends back new state information to the reinforcement machine learning agent which computes new policy and new value of action;
making a decision by the reinforcement machine learning agent and matching to a course of action; and
providing the course of action for execution.

12. The computer program product according to claim 11, further comprising post-processing the course of action.

13. The computer program product according to claim 11, wherein providing the course of action is providing the course of action to an operator.

14. The computer program product according to claim 11, wherein making the decision is done at an end of a simulation.
